(19) United States
(12) Patent Application Publication
(10) Pub. No.: US 2025/0279773 A1
(43) Pub. Date: Sep. 4, 2025

(54) PLANE TRANSITIONING AT A GLOBAL SWITCH BOX

(71) Applicant: Microsemi SoC Corp., Chandler, AZ (US)

(72) Inventors: Fei LI, San Jose, CA (US); Sinan KAPTANOGLU, Oakland, CA (US)

(21) Appl. No.: 19/067,601

(22) Filed: Feb. 28, 2025

Related U.S. Application Data
(60) Provisional application No. 63/560,693, filed on Mar. 2, 2024.

(51) Int. Cl. H03K 5/15

(52) U.S. Cl. CPC H03K 5/15013

(57) ABSTRACT

In some implementations, a first global switch box (GSB) may receive, via a first plane, a clock signal via a first clock index of a set of clock indices configured to receive clock signals via a clock routing channel. The first GSB may transition the clock signal to a second plane associated with a second clock index. The first GSB may provide, via the second plane, the clock signal to a second GSB via the second clock index. Implementations may provide the bi-directional connection and multiple quantities of such connections to bridge one index to many other indices for other planes.

### CROSS-REFERENCE TO RELATED APPLICATION

This Patent Application claims priority to Provisional Patent Application No. 63/560,693, filed on Mar. 2, 2024, and entitled “PLANE TRANSITIONING AT A GLOBAL SWITCH BOX.” The disclosure of the prior Application is considered part of and is incorporated by reference into this Patent Application.

### FIELD

The present disclosure generally relates to global switch boxes (GSBs) having multiple interplane connections between clock indices. A GSB is used to route clock signals from a global input block (GIB) to clock regions of a programmable logic device. For example, the GSB may receive a clock signal via a first clock index and send the clock signal via one or more of the first clock index in one or more directions, or via one or more other clock indices (or different planes) that are on a same or a different plane as the first clock index.

### BACKGROUND

A programmable logic device may include multiple clock regions that may be synchronized for proper function of the programmable logic device. The programmable logic device may include dies that include a set of clock regions (e.g., 8×8 clock regions). The programmable logic device may include, or be included in, a storage device (e.g., a non-volatile memory device, such as a negative-and (NAND) flash memory device). The programmable logic device may form clock routes for providing clock signaling to each of the clock regions of the computing device.

### SUMMARY

In some implementations, a method performed by a first global switch box (GSB) includes receiving, via a first plane, a clock signal via a first clock index of a set of clock indices configured to receive clock signals via a clock routing channel. The method includes transitioning the clock signal to a second plane associated with a second clock index. The method includes providing, via the second plane, the clock signal to a second GSB via the second clock index.

In some implementations, a system comprises a first GSB of a programmable logic device. The first GSB is to receive, via a first plane, a clock signal via a first clock index of a set of clock indices configured to receive clock signals via a clock routing channel. The first GSB is to transition, via a bi-directional interplane connection, the clock signal to a second plane associated with a second clock index. The first GSB is to provide, via the second plane, the clock signal to a second GSB via the second clock index.

In some implementations, a computer program product comprises one or more computer readable storage media and program instructions collectively stored on the one or more computer readable storage media. The program instructions comprise program instructions to receive, via a first plane of a GSB, a clock signal via a first clock index of a set of clock indices configured to receive clock signals via a clock routing channel, wherein the clock signal is transitioned to a second plane associated with a second clock index. The program instructions comprise program instruction to provide, via the second plane, the clock signal to a second GSB via the second clock index.

### BRIEF DESCRIPTION OF THE DRAWINGS

FIG. 1 is a diagram of an example of a global switch box (GSB) arranged to connect a clock index for a first plane with multiple clock indices for one or more additional planes described herein.

FIG. 2 is a diagram of an example of a bounding box having clock regions and an H-tree configuration for administering clock information.

FIG. 3 is a diagram of examples of GSB switching patterns.

FIG. 4 is a diagram of examples of global input block (GIB) configurations.

FIG. 5 is a diagram of an example of a bounding box having clock regions divided into two halves for administering clock information.

FIG. 6 is a diagram of example components of one or more devices of FIGS. 1-5.

FIGS. 7-9 are flowcharts of example processes associated with plane transitioning at a global switch box described herein.

### DETAILED DESCRIPTION

The following detailed description of example implementations refers to the accompanying drawings. The same reference numbers in different drawings may identify the same or similar elements.

A computing device may include multiple clock regions that may be synchronized for proper function of the computing device. For example, synchronization of clock regions supports time-based or sequential commands among the clock regions. Global network routing may use levels of H-trees to distribute a clock signal throughout the computing device (such as a programmable logic device). The programmable logic device may include a field programmable gate array (FPGA) chip.

The computing device (e.g., a field programmable gate array (FPGA)) may include an FPGA fabric that includes a repeated structure (e.g., a repeated pattern of substructures). For example, a clock mesh may be formed within the FPGA fabric, which includes a grid of conductive structures (e.g., metal wires) and global switch boards (GSBs) at intersections of the conductive structures. The computing device may use this clock mesh to distribute clock signaling, enable signaling, reset signaling, or control signaling to clock regions of the computing device. Timing of the signaling may be important for proper functioning of the computing device, so a configuration of the distribution of the signaling can affect performance of the computing device.

To improve performance, the computing device may use a signal distribution structure, such as a multi-level H-tree. The multi-level H-tree may be configured to use the conductive structures of the clock mesh as tree edges to carry signals between tree centers of adjacent levels of the H-tree (e.g., from level 2 tree center to 4 level 1 tree centers). The GSBs at intersections of the tree edges may be used to pass signals in a straight line, to change a direction of a signal, or to split a signal. In some aspects, a pathway within the computing device used to distribute clock signals may be referred to as a clock routing channel. The clock routing channel may include tree edges (e.g., metal wires or other conductive structures) or GSBs, among other examples.

The computing device may support N chip-wide clocks for all dies, N upper-half-chip clocks and N lower-half-chip clocks, regional clocks, or 2N chip-wide clocks. In some examples, N may be 24.

Global switch blocks (GSBs) may be located at intersections of clock stripes (e.g., intersections of clock region boundaries). GSBs at the top and bottom edges are called source GSBs (“Src GSB”). Although orientation of the top, bottom, left, and right edges may be based on perspective, for the purpose of this description, the GSBs at the top and at the bottom are next to clock generation peripheries. Because of the locations of the GSBs as being proximal to clock generation peripheries, after programming such a GSB, the GSBs can become a first GSB in clock routing operation to bring clock sources into the FPGA programmable fabric. These GSBs, as the source of clock information to the FPGA programmable fabric, may be referred to as the Source GSB. GSBs in the middle of the fabric may be programmed to be either sub-tree centers or to enable forming longer tree edges, depending on a technique used to program those GSBs. Regardless of the technique, the FPGA is to include one unique GSB to be programmed as the tree center at the highest level of the routing tree (H-tree). This tree center at the highest level of the routing tree may be referred to as the “root” GSB, since it is the root of the entire routing tree.

In some examples, an FPGA may be formed with clock regions and conductive channels (e.g., made of metal lines or wire). For example, the FPGA may be formed as a generic computing device that may be programmed for a specific use by a vendor or other user. There exist many techniques for programming an FPGA, such as register-transfer level (RTL) design that uses hardware description languages (HDLs) to define how data moves between registers and logic, high-level synthesis that uses coding to define hardware behavior and convert high-level code into HDL, graphical block-based design that uses drag-and-drop blocks, or soft processors and embedded systems where the FPGA includes an embedded processor. Other examples of techniques for programming an FPGA include partial reconfiguration where a system reconfigures portions of the FPGA while still using other parts of the FPGA, pipeline and parallel processing techniques that use parallel execution, custom instruction set extensions where the FPGA receives custom instructions for embedded processors, or domain-specific FPGA programming for processes such as machine learning or cryptography, among other examples. In different programming techniques, the same hardware of the FPGA may serve different purposes.

A root GSB, located within the chip, receives a clock signal (inclusive of a reset command or other signals to the clocks, such as an “enable” signal) from the source GSB and distributes the clock signal to clocks of each block.

FPGA clock tracks are metal wires located in the routing channels of a fixed length referred to as segments. The FPGA include switch boxes (e.g., GSBs) between those segments so that multiple segments can be connected to form longer connections or even change directions. There are a number of clock tracks in each segment and they are assigned with a numerical index. The GSB provides connection patterns between adjacent segments.

Different connection patterns may exhibit different timing characteristics. Among these patterns, one pattern may connect clock tracks of the same index from adjacent segments. As a result, clock tracks with the same index from all segments in the FPGA device can be connected together by programming all these GSBs and form a clock mesh made of clock tracks of the same index. This clock mesh made of clock tracks of the same index may be referred to as a clock plane.

A programming technique may use less than the entire clock plane across the device. In some examples, a system may program the GSBs so that a clock signal only traverses a portion of the entire clock plane. This may be referred to as routing the clock tree on this clock plane, which indicates that the system routes the signal for the expansion to be covered on the clock plane. If multiple domains do not spatially overlap with each other, then the system may route multiple clock signals on the same clock plane without shorting the signal. This conserves use clock planes that are limited within the FPGA device. If the clock domain bounding boxes overlap, then multiple clock planes are needed to route the clock signal to avoid conflicts. In this way, flexibility of the GSB to offer connection patterns within the clock plane or between different clock planes support different ways of programming the global network on the FPGA.

In some FPGA devices, clock tracks are physically the same in all clock routing segments. The concept of transmission and distribution tracks is associated with programming of the FPGA device so that the physical tracks serve different purposes in the clock routing topology than in data and signal routing. Routing tracks that are used to connect from a source GSB to a root GSB may be referred to as transmission tracks. Clock tracks used to build an H-tree may be referred to as distribution tracks.

In an example, a clock signal travels from a clock generator to flip-flops through a transmission track first (e.g., to connect the signal to the root of the H-tree), then is further distributed the H-tree root down to all of the flip-flops in a skew-balanced way. The transmission track routing affects the clock delay and distribution track routing affects the clock skew. Hence, it is beneficial to have different algorithms to route these two different types of clock routing. The distribution tracks may be assigned with clock planes first, which determines which clock index they are to occupy. Then the transmission track may use a negotiated congestion router (e.g., a router that employs a negotiated congestion routing algorithm) to find paths that avoid the conflict with distribution tracks' clock plane.

In some aspects described herein, a GSB may receive a clock signal via a first clock index for a first plane. The GSB may transition the clock signal to a second clock index for a second plane. The GSB may then provide the clock signal to another GSB via the second clock index for the second plane. In some aspects, the first index may have multiple interplanar connections through which the GSB can transition the clock signal to multiple other clock indices for many different planes. In this way, the GSB may switch between indices for different planes while supporting outputting the clock signal through one or more output clock indices.

Additionally, a series of GSBs may be used to send the clock signal from a first clock index to an end clock index by linking the first clock index to the end clock index via a series of transitions through interplanar connections between clock indices at the series of GSBs. In some aspects, this may allow a clock signal sent from a first global input block (GIB) to a clock index associated with a second GIB (e.g., based at least in part on the GIBs having limited connections that are less than a total number of clock indices). The GIB is an additional hardware component that sits between the clock generation periphery and the Source GSB. The GIB is to provide extra routing flexibility when bringing clock signals from a periphery circuit into the first GSB in the fabric (e.g., to allow for transmission on different planes).

In an example of a GSB, the GSB includes 48 clock indices. Each clock index is directly connected to 3 other clock indices (e.g., on a different plane (e.g., three different other planes)). Switching indices for those direct connects do not block any intermediate indices, which allows the GSB to route multiple clock signals. For example, the GSB can route multiple clock signals that do not overlap or use the same index for the same plane. After switching to a new index, a track may leave the GSB towards another GSB.

In some aspects, a computing device includes 48 clock indices that are partitioned into two groups. A source GSB that is paired with a GIB tile can use direct connects to jump from one index group in a GIB to another index group in the same GIB.

A source GSB and a GIB may work together to connect a first index group in the GIB to a clock index in the second index group in the same GIB. In some aspects, the source GSB may be located at the top and bottom edges of an array of clock regions. When the pair of the source GSB and the GIB are dedicated for delivering signals to a global network via transmission tracks, the pair can put the signals on any clock plane to begin distribution within the FPGA. For example, the pair can receive the clock signals from clock generation periphery circuits (e.g., a large circuit block), and use connection patterns from the GIB and the GSB together to place the clock signal on any clock plane without using any hardware resources outside of this pair of the GIB and the GSB (e.g., source GSB). In this way, the pair form an underlying hardware piece that supports flexible programmability methods.

A peripheral block clock may include a clock that is generated from an IO bank (e.g., a set of input/output pins) where clock generation circuits are located. Based at least in part on the clock and associated circuit blocks being outside of the FPGA fabric array, the clocks may be referred to as a peripheral block clock. The peripheral block clock is in different from any clock signals generated from within the FPGA array. For example, a system may program a ring-oscillator into an FPGA array, and use that generated signal as a clock. However, such a clock may have more jitter than a phased-lock loop (PLL) clock generated in peripheral blocks, or off-chip modulated clock signals coming from input/output circuits.

In some examples of clock signaling on clock planes, a fully occupied left group of 24 indices (left-index-group associated with 24 clock planes) can jump to the 24 indices in the right group (right-index-group associated with a different set of 24 clock planes) all together. This routing flexibility provides ways to jump from one group of clock planes to another group. For up to 24 clocks, the computing device can plan all the target indices in one group and impose no input/output (IO) placement constraint. A pair of indices with a direct connection can swap indices without interfering others. Or a used index can swap with an unused index.

A root GSB (for an H-tree) may be positioned in a middle portion of the FPGA fabric array (the repeated structure of the FPGA). When a distribution track (e.g., a clock signal path exiting from the root GSB toward leaves or intermediate H-tree centers) is assigned on an index (e.g., associated with a first clock plane) of a left index-group (a first set of indices), the transmission track can be routed (e.g., coming from the source GSB into Root GSB) on an index of the right index-group (e.g., a second set of indices). In this way, the transmission track (e.g., associated with data and signal routing) and the distribution track (e.g., associated with clock signals, control signals, reset signals, or enable signals, among other examples) may not interfere. Partitioning into two index groups (e.g., each of size 24) may support routing of up to 24 full-chip clocks.

In some aspects, distribution tracks may occupy tracks on either a bottom or a top edge of the array. When a source GSB, GIB, or a pair of a source GSB and a GIB collides with its own distribution track, interference can be avoided based at least in part on using different planes or index groups for up to 24 chip-wide clocks.

In some aspects, a root GSB may also occupy either the bottom or top edge. When a source GSB, GIB, or source GSB+GIB collides with a root GSB, interference can still be avoided based at least in part on using different planes or index groups for up to 24 chip-wide clocks.

These techniques may improve clock signal routing for a computing device having 24 chip-wide clocks. For example, the computing device may use the partition scheme of separating clock indices into two groups at the GIB. In some examples, the computing device may assign the left index-group for distribution tracks and the right index-group for transmission tracks. The computing device may use the source GSB and the GIB to get on those transmission track indices. A router (e.g., a vendor software component that does the routing of a user design implementation on the FPGA device) can find such solutions for transmission tracks. In some aspects, the router may find different solutions. In some aspects, H-tree layer assignments may be used along with these techniques to achieve 24 chip-wide clocks (e.g., knowledge at the router or the computing device of the H-tree layer assignment).

In some aspects, the computing device (e.g., the programmable logic device) may support additional clocks based at least in part on applying half-chip (or other division of the chip) regional constraints. Some techniques use a flow for users to apply half-chip regional constraints to a clock domain's flip-flops (targets that a clock signal is to reach) to achieve more clocks on the chip. For example, up to 36 such clocks may be allowed on some chips. In some aspects, no additional IO placement constraints are imposed on users. This allows a user to decide where the input/output circuits for FPGA designs are to be mapped onto the FPGA. In this way, a user may have increased control of a printed circuit board design. The global network and clock routing technique described does not impose additional constraints, which supports additional input/output circuit placement and PCB design via the programmable global network and corresponding H-tree programming.

In some examples, the computing device may include M clock domains (flip-flops clocked by the same clock) constrained to an upper half of the chip wherein M is less than or equal to 24. Similarly, the computing device may include N clock domains constrained to a lower half of the chip wherein N is less than or equal to 24. For each half of the die, treating them as if they are separate chips, distribution and transmission tracks may follow the index group scheme (e.g., where clock indices are organized into groups, such as the two-group scheme described) as prescribed previously to support up to 24 clocks. In reality, the two half chips still share the common clock stripes at their abutting boundaries. The two half chips may use different index groups for their associated distribution tracks. H-tree topology selection for the two half chips may ensure that root GSBs are not in the common clock stripes. This makes sure the transmission tracks in the two half chips do not have to use the common clock stripes.

To support additional clocks with the half-chip configuration, one or more aspects of the following procedure may be implemented. Post-placement, the computing device may find a top and bottom partition of the chip, where (after excluding K clock domains that are small regional clocks that are to be handled separately) there are M clock domains placed entirely within the upper half, N clock domains placed entirely within the lower half, and G clock domains that are placed in both partitions. The computing device may choose the partition to find a highest value of M+N, subject to M and N being less than or equal to 24 and G being less than or equal to 24—the greater of M or N (e.g., 24−Max(M,N). If no such partition exists, the computing device may pick the partition that gives the smallest violations, (e.g., min{(M>24?(M−24):0)+(N>24?(N−24):0)+(G>24−max(M,N)?G−(24−max(M,N)):0}.

The computing device may assign a left-index-group to distribution tracks of M clock domains. If M is less than or equal to 24, a negotiated congestion router for the transmission tracks is expected to find solutions with the right-index-group. If M>24, the computing device may call a Boolean Satisfiability solver (SAT solver) for these M clock domains to make the left-index-group cover the distribution tracks of all M clock domains, then transmission routing can find solutions with the right-index-group. If the SAT solver gives no solution, the computing device may spill over to the right-index-group for distribution tracks, but transmission routing solutions may not be supported later based at least in part on the spill over.

The computing device may assign the right-index-group to distribution tracks of N clock domains. When Nis less than or equal to 24, the negotiated congestion router for the transmission tracks is expected to find solutions with left-index-group. If N>24, the computing device may call the SAT solver for these N clock domains to make the right-index-group cover the distribution tracks of all N clock domains, then transmission routing can find solutions with the left-index-group. If the SAT solver gives no solution, spill over to the left-index-group, transmission routing solutions may not be supported later.

The computing device may assume m unused clock indices in the left-index-group and n unused indices in right-index-group from the previous distribution track layer assignment. Assume m is less than or equal to n without loss of generality. Assign m unused clock indices for distribution tracks in G clock domains. If m<G and all G clocks are chip-wide clocks, declare layer assignment failure and stop. If G clocks are not all chip-wide clocks, but span just two partitions partially, find any available unused indices for G clocks' distribution tracks. Then, proceed to transmission routing.

In some aspects, the computing device may attempt to configure many small regional clock domains and a few chip-wide system clocks. For example, the computing device may use a small receiver (RX) clock domain size before it transfers to system clock domain. A transmitter (TX) clock domain can be small, or can be combined into the system clock.

The RX clock domain is expected to be ˜2K LEs. For a chip-wide clock (or large size system clock), a distribution track layer assignment may be placed on a left-index-group. The router may find right-index-group for transmission tracks. Regional clocks of 1˜2 CRs may use distribution track layer assignment done by the SAT solver. The router finds the solution of the same index for transmission tracks existing in the source GSB. Similar techniques may be used for serialization and deserialization (SERDES) interface TX/RX clocks at the bottom side.

To reach 48 chip-wide clocks, the computing device may apply additional operations of distribution track layer assignment based on input/output bank (IOBANK) placement and distribution track topology orientation selection based on IOBANK placement. An IOBANK may refer to a set of IO circuits that are arranged in a banks the same voltage level. Different IOBANKS can be programmed on the FPGA to provide different voltage levels, which may support different Input/Output electrical standards.

For each clock signal, a global IO placement determines which edge (top or bottom) a source GSB and GIB (“Src GSB+GIB”) is located and selects a distribution track topology orientation based on the location. This may improve a likelihood that the source GSB and GIB does not interfere with its own distribution track. All clock sources on one edge may be contained within one source GSB and GIB and a distribution track layer assignment may be determined for IO placement.

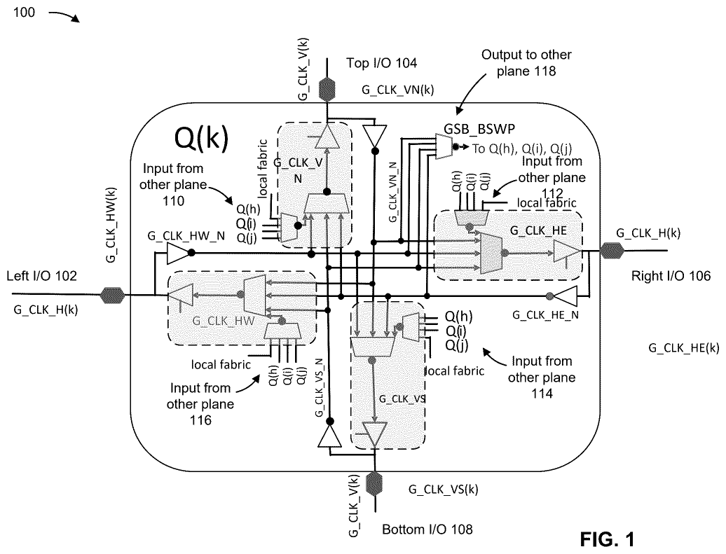

FIG. 1 is a diagram of an example 100 of a GSB arranged to connect a clock index for a first plane with multiple clock indices on other planes described herein. As shown in FIG. 1, the GSB may receive signals (e.g., clock signals, resets, enable commands, among other examples) from any of four directions. For example, the GSB may receive signals via a left input/output (I/O) 102, a top I/O 104, an right I/O 106, or a bottom I/O 108. Similarly, the GSB may provide signals via any of the left I/O 102, the top I/O 104, the right I/O 106, or the bottom I/O 108.

In some aspects, the GSB may be positioned at an intersection (e.g., a corner) of four clock regions or two clock regions and an edge of a clock region array.

Once the signal is received at the GSB, the signal may be routed in one or more directions having an output connection. In this way, the GSB may pass the signal along in a straight path from reception or cause the signal to change directions.

As also shown in FIG. 1, the GSB may include a set of inputs from other planes (of clock tracks) 110, 112, 114, and 116. In some aspects, the plane shown may be a first plane Q(k) and the other planes may include Q(h), Q(i), or Q(j). In some aspects, Q(h), Q(i), or Q(j) may be clock indices for other planes that are different from the first plane. In this way, the GSB may be configured to transition a signal from the other planes to the first plane.

As further shown in FIG. 1, the GSB may include a set of outputs to other planes (of clock tracks) 118. For example, the GSB may support transitioning a received signal to Q(h), Q(i), or Q(j) on one or more planes that are different from the first plane. In this way, the GSB may be configured to transition a signal from the first plane to one or more other planes.

In some aspects, the GSB may provide the signal as an output on one plane (e.g., the first plane or a plane associated with Q(h), Q(i), or Q(j)) or via multiple planes. In some aspects, the GSB may provide the signal as an output on multiple clock tracks (e.g., two clock paths for an H-tree distribution).

The number and arrangement of components shown in FIG. 1 are provided as an example.

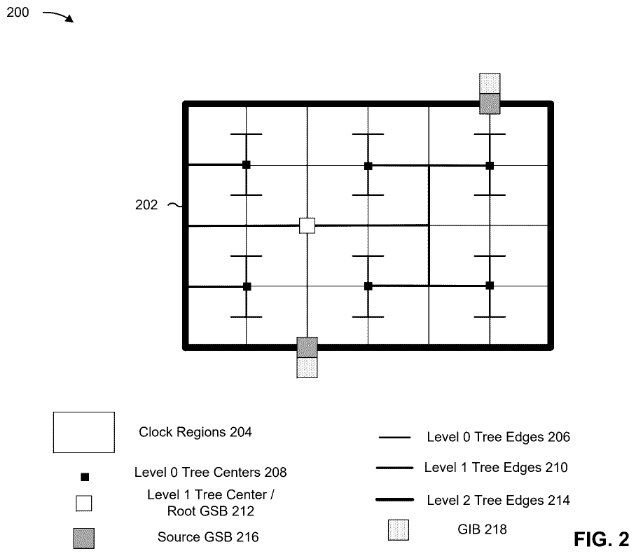

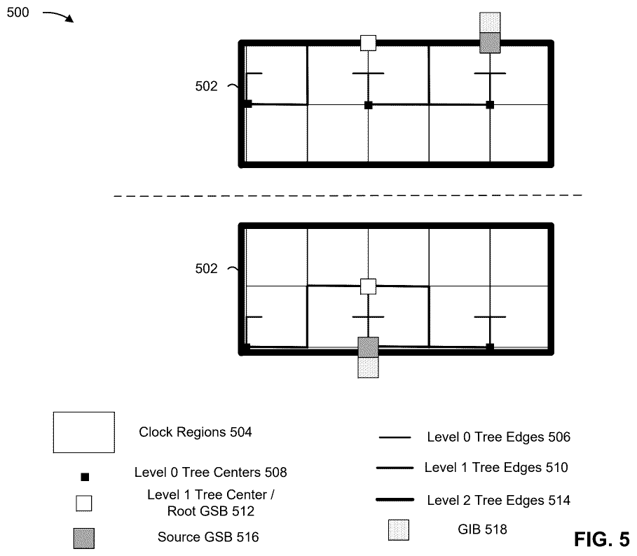

FIG. 2 is a diagram of an example 200 of a bounding box 202 having clock regions and an H-tree configuration for administering clock information. In context of FIGS. 2 and 5 tree edges may be used to represent conductive structures of a computing device (e.g., FPGA) and tree centers may be used to represent GSBs of the computing device. In this way, the tree centers may operate as nodes through with the computing device may send signaling (e.g., clock signals) to clock regions of the computing device and the tree edges may be used as conductive material to carry the signal between nodes. Once an H-tree is configured, as shown in FIGS. 2 and 5, the computing device may use the H-tree as a distribution path for signals such as clock signals.

As shown in FIG. 2, a computing device (e.g., an FPGA) may include clock regions 204. A level 0 of an H-tree for distributing clock information may include level 0 tree edges 206 connecting the clock regions 204 to Level 0 tree centers 208. Level 0 may be formed with the level 0 tree edges 206 in a shape of a full or partial “H” shape with the level 0 tree centers 208 in a center of the “H” shape formed by the level 0 tree edges 206 (or where the center would be if the “H” was a full “H”).

A level 1 of the H-tree may include level 1 tree edges 210 connecting the level 1 tree centers 208 to a level 1 tree center (a root GSB) 212. Level 1 may be formed with the level 1 tree edges 210 in a shape of a full or partial “H” shape with the level 1 tree centers 212 in a center of the “H” shape formed by the level 1 tree edges 210 (or where the center would be if the “H” was a full “H”).

When forming the level 1 of the H-tree, the computing device may configure H-shaped (full or partial) level 1 tree edges 210 that connect each of the level 0 tree centers 208 to a level 1 tree center 212. If possible, each level 0 tree center 208 may be equally distant from an associated level 1 tree center 212 along the level 1 tree edges 210.

The level 1 tree center 212 may be a root GSB 212 based at least in part on being connected via level 2 tree edges 214 to a source GSB 216 located at an edge of the bounding box associated with the clock regions 204. In some aspects, the root GSB 212 receives a clock information (e.g., a clock signal, a reset, or enable signals, among other examples) from the source GSB 216 to send to the clocks of the clock regions 204. The source GSB 216 may receive the clock information from the GIB 218 (e.g., via a communication channel).

In some aspects, additional GSBs are located at intersections of the tree edges or at corners of the clock regions 204. The clock information may be directed at the corners of the tree edges based at least in part on the GSBs receiving the clock information via an input (e.g., shown in FIG. 1) and providing the clock information via an output. In some aspects, tree edges of different levels of the H-tree may overlap, which may cause interference. In these cases, the GSBs may transfer overlapping clock information to different plans to avoid or reduce interference.

The number and arrangement of components shown in FIG. 2 are provided as an example.

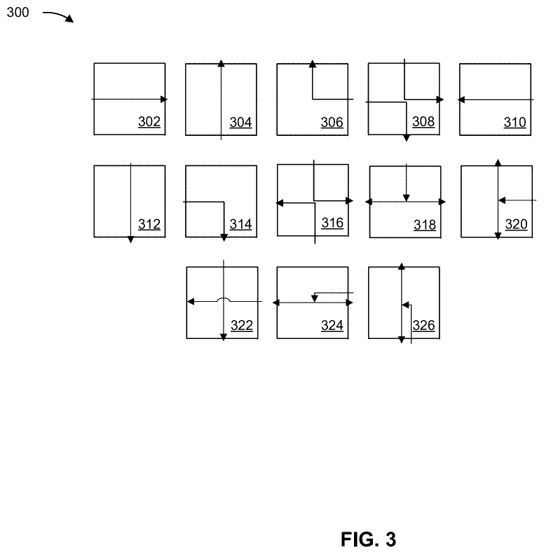

FIG. 3 is a diagram of examples of GSB switching patterns. Example 302 shows a left to right switching pattern. Example 304 shows a bottom to top switching pattern. Example 306 shows an right to top switching pattern. Example 308 shows a left to bottom and an right to top switching pattern. Example 310 shows an right to left switching pattern. Example 312 shows a top to bottom switching pattern. Example 314 shows a left to bottom switching pattern. Example 316 shows a bottom to left and a top to right switching pattern. Example 318 shows a top to left and right switching pattern. Example 320 shows an right to top and bottom switching pattern. Example 322 shows a top to bottom and an right to left switching pattern. Examples 302 through 322 may be associated with connection patterns between a same clock index.

Examples 324 and 326 are associated with connection patterns between different bit indices. Example 324 shows an right (e.g., on a first clock index) to right and left (e.g., on a second clock index) switching pattern. Example 326 shows a bottom (e.g., on a first clock index) to bottom and top (e.g., on a second clock index) switching pattern

The number and arrangement of components shown in FIG. 3 are provided as examples. Other examples of switching patterns are not shown.

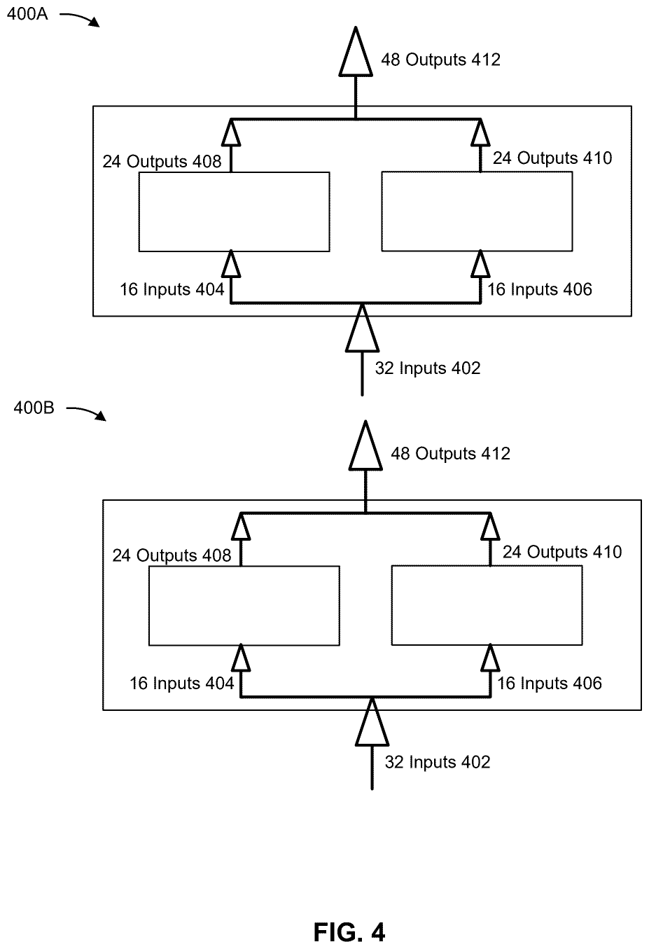

FIG. 4 is a diagram of examples 400A and 400B of GIB configurations. As shown in example 400A, a GIB tile may include a first chip 402 and a second chip 404. In some aspects, the chips may be configured with 24 output channels (e.g., pins) and 16 input channels, such that the chips are 16×24 chips (e.g., xbars).

The GIB tile may receive 32 inputs 406, which may be divided, with a portion sent to each of the first chip 402 and the second chip 404. For example, the first chip 402 may receive 16 inputs 408 and the second chip 404 may receive 16 inputs 410. In some aspects, the first chip 402 and the second chip 404 may be configured to receive signals via the respective inputs, but may not receive signals via each input.

The first chip 402 may provide connections from the 16 inputs 408 to 24 outputs 412 and the second chip 404 may provide connections from the 16 inputs 410 to 24 outputs 414. The GIB tile may provide the 24 outputs 412 and the 24 outputs 414 as 48 total outputs 416 to another tile (e.g., a GSB) for further connections between inputs and outputs.

In some aspects, inputs may be connected to multiple outputs, with the first chip 402 or the second chip 404 to select or implements a selection (e.g., of one or more outputs) of an available connection on which the first chip 402 or the second chip 404 is to provide signals received via an input. In some aspects, one or more of the multiple outputs may be associated with a plane that is different from a plane with which the input is associated. In some aspects, the first chip 402, the second chip 404, or chips of a GSB or other GIB may use multiple sequential connections between inputs and outputs to transfer an input signal to a target output (e.g., sequential GSBs or GIBs may be used to create a link between an input and a target output).

The number and arrangement of components shown in FIG. 4 are provided as examples. Other examples of GIB configurations are not shown.

FIG. 5 is a diagram of an example 500 of a bounding box 502 having clock regions divided into two halves for administering clock information. As shown in FIG. 5, a computing device (e.g., an FPGA) may include clock regions 504. A level 0 of an H-tree for distributing clock information may include level 0 tree edges 506 connecting the clock regions 504 to Level 0 tree centers 508. A level 1 of the H-tree may include level 1 tree edges 510 connecting the level 1 tree centers 508 to a level 1 tree center (a root GSB) 512.

The level 1 tree center 512 may be a root GSB 512 based at least in part on being connected to a source GSB 514 located at an edge of the bounding box associated with the clock regions 504. In some aspects, the root GSB 512 receives a clock information (e.g., a clock signal, a reset, or enable signals, among other examples) from the source GSB 514 to send to the clocks of the clock regions 504. The source GSB 514 may receive the clock information from the GIB 516 (e.g., via a communication channel).

As shown in FIG. 5, the bounding box may be (e.g., logically) divided into two parts (e.g., two portions of the bounding box). A first part (e.g., an upper part) and a second part (e.g., a lower part) may function as separate chips for administration of clock information. For example, tree edges (e.g., distribution and transmission tracks) are to follow an index group scheme (e.g., as prescribed previously to support up to 24 clocks). However, the two parts of the chip still share common clock stripes at a boundary. The two parts of the chip use different index groups for distribution tracks (e.g., tree edges). An H-tree topology for the two parts of the chip are configured such that root GSBs are not in the common clock stripes (e.g., at the boundary). In this way, the transmission tracks in the two parts of the chip do not use the common clock stripes.

The number and arrangement of components shown in FIG. 5 are provided as an example.

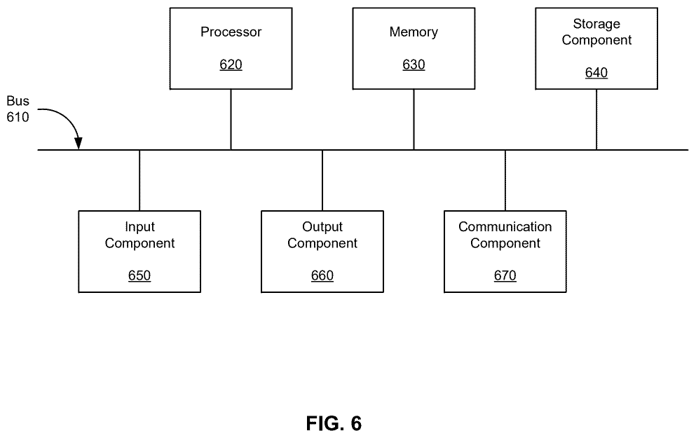

FIG. 6 is a diagram of example components of a device 600, which may correspond to one or more devices of FIG. 1, such as a GSB. The one or more devices may include one or more programmable logic devices (PLDs) with clock circuitry such as the GSB of FIG. 1. In some aspects, the device 600 may correspond to one or more other devices, such as an FPGA, a controller, a computing device, or a programmable logic device, among other examples. In some implementations, the GSB, FPGA, placer, router, controller, computing device, or programmable logic device, may include one or more devices 600 and one or more components of device 600 may include one or more of the GSB, FPGA, placer, router, controller, computing device, or programmable logic device. As shown in FIG. 6, device 600 may include a bus 610, a processor 620, a memory 630, a storage component 640, an input component 650, an output component 660, and a communication component 670.

Bus 610 includes a component that enables wired or wireless communication among the components of device 600. Processor 620 includes a central processing unit, a graphics processing unit, a microprocessor, a controller, a microcontroller, a digital signal processor, a programmable logic device such as a field-programmable gate array, an application-specific integrated circuit, or another type of processing component. Processor 620 is implemented in hardware, firmware, or a combination of hardware and software. In some implementations, processor 620 includes one or more processors capable of being programmed to perform a function. Memory 630 includes a random access memory, a read only memory, or another type of memory (e.g., a flash memory, a magnetic memory, or an optical memory).

Storage component 640 stores information or software related to the operation of device 600. For example, storage component 640 may include a hard disk drive, a magnetic disk drive, an optical disk drive, a solid state disk drive, a compact disc, a digital versatile disc, or another type of non-transitory computer-readable medium. Input component 650 enables device 600 to receive input, such as user input or sensed inputs. For example, input component 650 may include a touch screen, a keyboard, a keypad, a mouse, a button, a microphone, a switch, a sensor, a global positioning system component, an accelerometer, a gyroscope, or an actuator.

Output component 660 enables device 600 to provide output, such as via a display, a speaker, or one or more light-emitting diodes. Communication component 670 enables device 600 to communicate with other devices, such as via a wired connection or a wireless connection. For example, communication component 670 may include a receiver, a transmitter, a transceiver, a modem, a network interface card, or an antenna.

Device 600 may perform one or more processes described herein. For example, a non-transitory computer-readable medium (e.g., memory 630 or storage component 640) may store a set of instructions (e.g., one or more instructions, code, software code, or program code) for execution by processor 620. Processor 620 may execute the set of instructions to perform one or more processes described herein. In some implementations, execution of the set of instructions, by one or more processors 620, causes the one or more processors 620 or the device 600 to perform one or more processes described herein. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

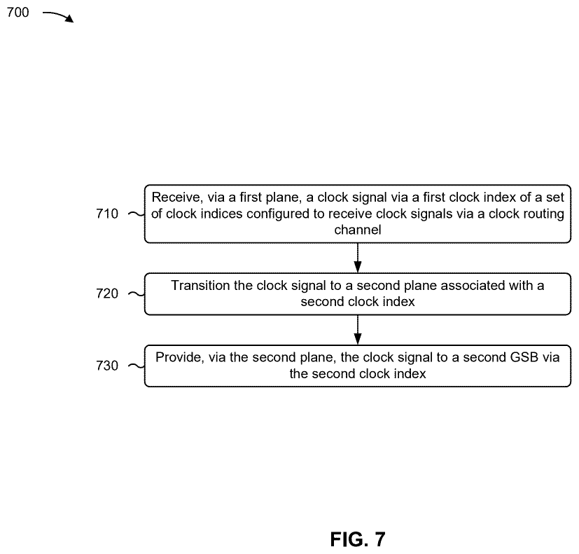

FIG. 7 is a flowchart of an example process 700 associated with plane transitioning at a global switch box field brief description of the drawings. In some implementations, one or more process blocks of FIG. 7 may be performed by a first GSB (e.g., as described in connection with FIG. 1 or in connection with any of FIGS. 1-5). Additionally, or alternatively, one or more process blocks of FIG. 7 may be performed by one or more components of device 600, such as processor 620, memory 630, storage component 640, input component 650, output component 660, and/or communication component 670.

As shown in FIG. 7, process 700 may include receiving, via a first plane, a clock signal via a first clock index of a set of clock indices configured to receive clock signals via a clock routing channel (block 710). For example, the GSB may receive, via a first plane, a clock signal via a first clock index of a set of clock indices configured to receive clock signals via a clock routing channel, as described above (e.g., in connection with FIG. 1 showing a GSB that receives signals via various planes). In some aspects, the clock routing channel may include pathways (e.g., conductive pathways including tree edges, wires, GSBs, or other electrically conductive components) within a computing device (e.g., an FPGA) that are used to distribute clock signals throughout a computer chip (e.g., the FPGA).

As further shown in FIG. 7, process 700 may include transitioning the clock signal to a second plane associated with a second clock index (block 720). For example, the GSB may transition the clock signal to a second plane associated with a second clock index, as described above (e.g., in connection with FIG. 1 showing an input signal entering on a first plane and exiting on a different plane).

As further shown in FIG. 7, process 700 may include providing, via the second plane, the clock signal to a second GSB via the second clock index (block 730). For example, the GSB may provide, via the second plane, the clock signal to a second GSB via the second clock index, as described above (e.g., in connection with FIGS. 1 and 2 where a signal enters the GSB on a first plane and exists on a different plane, then is forwarded to another GSB, such as a lower level GSB or a root GSB).

Process 700 may include additional implementations, such as any single implementation or any combination of implementations described below and/or in connection with one or more other processes described elsewhere herein.

In a first implementation, transitioning the clock signal to the second plane comprises transitioning the clock signal to the second plane via a bi-directional interplane connection.

In a second implementation, alone or in combination with the first implementation, the first clock index is connected to the second plane via multiple interplane connections with clock indices for the second plane.

In a third implementation, alone or in combination with one or more of the first and second implementations, process 700 includes providing the clock signal to a third GSB via the first plane.

In a fourth implementation, alone or in combination with one or more of the first through third implementations, the first clock index is associated with a first global input block (GIB), and wherein the second clock index is associated with a second GIB.

In a fifth implementation, alone or in combination with one or more of the first through fourth implementations, the first GSB comprises a source GSB.

In a sixth implementation, alone or in combination with one or more of the first through fifth implementations, the source GSB is co-located with a root GSB.

In a seventh implementation, alone or in combination with one or more of the first through sixth implementations, providing the clock signal to the second GSB via the second clock index comprises providing the clock signal on a clock route that is configured as a distribution track for a root GSB to distribute the clock signal after receipt from the first GSB.

In an eighth implementation, alone or in combination with one or more of the first through seventh implementations, the first GSB is associated with a first set of clock domains of a programmable logic device, wherein an additional GSB is associated with a second set of clock domains of the programmable logic device, and wherein the first set of clock domains and the second set of clock domains are separated by a boundary.

In a ninth implementation, alone or in combination with one or more of the first through eighth implementations, a root GSB associated with the first set of clock domains is positioned off of the boundary.

Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel. In some aspects, implementations or features described in connection with process 700 may be added to, or replaced with, those of processes 800 or 900. Similarly, implementations or features described in connection with processes 800 or 900 may be added to, or replaced with, those of process 700.

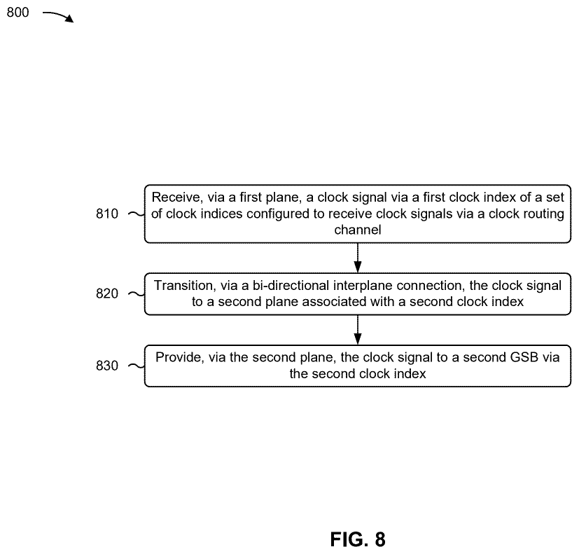

FIG. 8 is a flowchart of an example process 800 associated with plane transitioning at a global switch box field brief description of the drawings. In some implementations, one or more process blocks of FIG. 8 may be performed by a first GSB (e.g., as described in connection with FIG. 8 or in connection with any of FIGS. 1-5). Additionally, or alternatively, one or more process blocks of FIG. 8 may be performed by one or more components of device 600, such as processor 620, memory 630, storage component 640, input component 650, output component 660, and/or communication component 670.

As shown in FIG. 8, process 800 may include receiving, via a first plane, a clock signal via a first clock index of a set of clock indices configured to receive clock signals via a clock routing channel (block 810). For example, the GSB may receive, via a first plane, a clock signal via a first clock index of a set of clock indices configured to receive clock signals via a clock routing channel, as described above (e.g., in connection with FIG. 1 showing a GSB that receives signals via various planes). In some aspects, the clock routing channel may include pathways (e.g., conductive pathways including tree edges, wires, GSBs, or other electrically conductive components) within a computing device (e.g., an FPGA) that are used to distribute clock signals throughout a computer chip (e.g., the FPGA).

As further shown in FIG. 8, process 800 may include transitioning, via a bi-directional interplane connection, the clock signal to a second plane associated with a second clock index (block 820). For example, the GSB may transition, via a bi-directional interplane connection, the clock signal to a second plane associated with a second clock index, as described above (e.g., in connection with FIG. 1 showing an input signal entering on a first plane and exiting on a different plane).

As further shown in FIG. 8, process 800 may include providing, via the second plane, the clock signal to a second GSB via the second clock index (block 830). For example, the GSB may provide, via the second plane, the clock signal to a second GSB via the second clock index, as described above (e.g., in connection with FIGS. 1 and 2 where a signal enters the GSB on a first plane and exists on a different plane, then is forwarded to another GSB, such as a lower level GSB or a root GSB).

Process 800 may include additional implementations, such as any single implementation or any combination of implementations described below and/or in connection with one or more other processes described elsewhere herein.

In a first implementation, the first GSB comprises a set of clock indices configured to receive clock signals via a clock routing channel, and a set of interplane connections that provide links between each clock index and multiple additional clock indices.

In a second implementation, alone or in combination with the first implementation, the first clock index is connected to the second plane via multiple interplane connections with clock indices for the second plane.

In a third implementation, alone or in combination with one or more of the first and second implementations, providing the clock signal to the second GSB via the second clock index comprises providing the clock signal on a clock route that is configured as a distribution track for a root GSB to distribute the clock signal after receipt from the first GSB.

Although FIG. 8 shows example blocks of process 800, in some implementations, process 800 may include additional blocks, fewer blocks, different blocks, or differently arranged blocks than those depicted in FIG. 8. Additionally, or alternatively, two or more of the blocks of process 800 may be performed in parallel. In some aspects, implementations or features described in connection with process 800 may be added to, or replaced with, those of processes 700 or 900. Similarly, implementations or features described in connection with processes 700 or 900 may be added to, or replaced with, those of process 800.

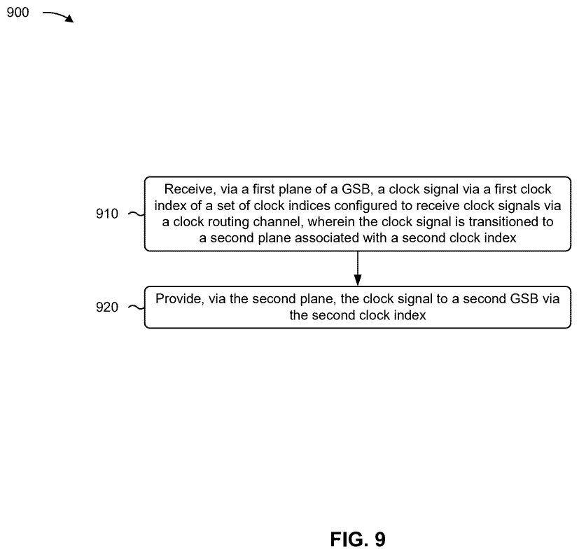

FIG. 9 is a flowchart of an example process 900 associated with plane transitioning at a global switch box field brief description of the drawings. In some implementations, one or more process blocks of FIG. 9 may be performed by a first GSB (e.g., as described in connection with FIG. 9 or in connection with any of FIGS. 1-5). Additionally, or alternatively, one or more process blocks of FIG. 9 may be performed by one or more components of device 600, such as processor 620, memory 630, storage component 640, input component 650, output component 660, and/or communication component 670.

As shown in FIG. 9, process 900 may include receiving, via a first plane of a GSB, a clock signal via a first clock index of a set of clock indices configured to receive clock signals via a clock routing channel, wherein the clock signal is transitioned to a second plane associated with a second clock index (block 910). For example, the GSB may receive, via a first plane of a GSB, a clock signal via a first clock index of a set of clock indices configured to receive clock signals via a clock routing channel, wherein the clock signal is transitioned to a second plane associated with a second clock index, as described above (e.g., in connection with FIG. 1 showing an input signal entering on a first plane and exiting on a different plane).

As further shown in FIG. 9, process 900 may include providing, via the second plane, the clock signal to a second GSB via the second clock index (block 920). For example, the GSB may provide, via the second plane, the clock signal to a second GSB via the second clock index, as described above (e.g., in connection with FIGS. 1 and 2 where a signal enters the GSB on a first plane and exists on a different plane, then is forwarded to another GSB, such as a lower level GSB or a root GSB).

Process 900 may include additional implementations, such as any single implementation or any combination of implementations described below and/or in connection with one or more other processes described elsewhere herein.

In a first implementation, process 900 includes providing the clock signal to a third GSB via the first plane.

In a second implementation, alone or in combination with the first implementation, the first clock index is associated with a first global input block (GIB), and wherein the second clock index is associated with a second GIB.

In a third implementation, alone or in combination with one or more of the first and second implementations, the first GSB comprises a source GSB.

In a fourth implementation, alone or in combination with one or more of the first through third implementations, the source GSB is co-located with a root GSB.

In a fifth implementation, alone or in combination with one or more of the first through fourth implementations, providing the clock signal to the second GSB via the second clock index comprises providing the clock signal on a clock route that is configured as a distribution track for a root GSB to distribute the clock signal after receipt from the first GSB.

In a sixth implementation, alone or in combination with one or more of the first through fifth implementations, the first GSB is associated with a first set of clock domains of a programmable logic device, wherein an additional GSB is associated with a second set of clock domains of the programmable logic device, and wherein the first set of clock domains and the second set of clock domains are separated by a boundary.

Although FIG. 9 shows example blocks of process 900, in some implementations, process 900 may include additional blocks, fewer blocks, different blocks, or differently arranged blocks than those depicted in FIG. 9. Additionally, or alternatively, two or more of the blocks of process 900 may be performed in parallel. In some aspects, implementations or features described in connection with process 900 may be added to, or replaced with, those of processes 700 or 700. Similarly, implementations or features described in connection with processes 700 or 700 may be added to, or replaced with, those of process 900.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual specialized control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method performed by a first global switch box (GSB), the method comprising:
receiving, via a first plane, a clock signal via a first clock index of a set of clock indices configured to receive clock signals via a clock routing channel;
transitioning the clock signal to a second plane associated with a second clock index; and
providing, via the second plane, the clock signal to a second GSB via the second clock index.

2. The method of claim 1, wherein transitioning the clock signal to the second plane comprises:
transitioning the clock signal to the second plane via a bi-directional interplane connection.

3. The method of claim 2, wherein the first clock index is connected to the second plane via multiple interplane connections with clock indices for the second plane.

4. The method of claim 1, comprising:
providing the clock signal to a third GSB via the first plane.

5. The method of claim 1, wherein the first clock index is associated with a first global input block (GIB), and
wherein the second clock index is associated with a second GIB.

6. The method of claim 1, wherein the first GSB comprises a source GSB.

7. The method of claim 6, wherein the source GSB is co-located with a root GSB.

8. The method of claim 1, wherein providing the clock signal to the second GSB via the second clock index comprises:
providing the clock signal on a clock route that is configured as a distribution track for a root GSB to distribute the clock signal after receipt from the first GSB.

9. The method of claim 1, wherein the first GSB is associated with a first set of clock domains of a programmable logic device,
wherein an additional GSB is associated with a second set of clock domains of the programmable logic device, and
wherein the first set of clock domains and the second set of clock domains are separated by a boundary.

10. The method of claim 9, wherein a root GSB associated with the first set of clock domains is positioned off of the boundary.

11. A system comprising:
a first global switch box (GSB) of a programmable logic device, the first GSB to:
receive, via a first plane, a clock signal via a first clock index of a set of clock indices configured to receive clock signals via a clock routing channel;
transition, via a bi-directional interplane connection, the clock signal to a second plane associated with a second clock index; and
provide, via the second plane, the clock signal to a second GSB via the second clock index.

12. The system of claim 11, wherein the first GSB comprises:
a set of clock indices configured to receive clock signals via a clock routing channel, and
a set of interplane connections that provide links between each clock index and multiple additional clock indices.

13. The system of claim 11, wherein the first clock index is connected to the second plane via multiple interplane connections with clock indices for the second plane.

14. The system of claim 11, wherein, to provide the clock signal to the second GSB via the second clock index, the first GSB is to:
provide the clock signal on a clock route that is configured as a distribution track for a root GSB to distribute the clock signal after receipt from the first GSB.

15. A computer program product comprising:
one or more computer readable storage media, and program instructions collectively stored on the one or more computer readable storage media, the program instructions comprising:
program instructions to receive, via a first plane of a global switch box (GSB), a clock signal via a first clock index of a set of clock indices configured to receive clock signals via a clock routing channel, wherein the clock signal is transitioned to a second plane associated with a second clock index; and
program instruction to provide, via the second plane, the clock signal to a second GSB via the second clock index.

16. The computer program product of claim 15, wherein the program instructions comprise:
program instructions to provide the clock signal to a third GSB via the first plane.

17. The computer program product of claim 15, wherein the first clock index is associated with a first global input block (GIB), and
wherein the second clock index is associated with a second GIB.

18. The computer program product of claim 15, wherein the first GSB comprises a source GSB.

19. The computer program product of claim 18, wherein the source GSB is co-located with a root GSB.

20. The computer program product of claim 15, wherein, to provide the clock signal to the second GSB via the second clock index, the program instructions comprise:
program instructions to provide the clock signal on a clock route that is configured as a distribution track for a root GSB to distribute the clock signal after receipt from the first GSB.

21. The computer program product of claim 15, wherein the first GSB is associated with a first set of clock domains of a programmable logic device,
wherein an additional GSB is associated with a second set of clock domains of the programmable logic device, and
wherein the first set of clock domains and the second set of clock domains are separated by a boundary.
